(19) United States
(12) Patent Application Publication
(10) Pub. No.: US 2013/0050044 A1
(43) Pub. Date: Feb. 28, 2013

(54) PLANE-STRUCTURED EBG

(71) Applicant: Daisuke INOUE, Chiyoda-ku (JP)

(72) Inventor: Daisuke INOUE, Chiyoda-ku (JP)

(21) Appl. No.: 13/660,305

(22) Filed: Oct. 25, 2012

Related U.S. Application Data
(63) Continuation of application No. PCT/JP2011/059607, filed on Apr. 19, 2011.

(30) Foreign Application Priority Data
Apr. 28, 2010 (JP) 2010-104500

(51) Int. Cl. H01Q 1/52; H05K 1/02

(52) U.S. Cl. 343/841; 174/250

(57) ABSTRACT

Disclosed is a planar EBG structure that can secure a highly efficient radio-wave propagation suppression effect using residual space that is smaller than one whole planar EBG element. By means of structuring EBG elements provided as a row (edge row) of one of the edge parts of the planar EBG structure in a manner so as to be severed at a position that is smaller than the width of the EBG element, the radio-wave propagation suppression effect of the planar EBG structure can be improved with a small number of rows. Specifically, by means of causing the edge row of EBG elements to be at least ¾ and less than 1, a high radio-wave propagation suppression effect can be obtained with a simple structure.

### TECHNICAL FIELD

The present invention relates to radio-wave propagation suppression using EBG of a planar structure and particularly relates to plane-structured EBG for obtaining a more efficient radio-wave propagation suppression effect in small space when it is difficult to ensure sufficient space.

### BACKGROUND ART

Recently, the research and development of controlling propagation of target radio waves by using an EBG (Electromagnetic Band Gap) structure in which predetermined structures smaller than target wavelengths are cyclically disposed has been underway.

For example, unnecessary radiation at an antenna can be suppressed, and propagation of radio waves can be suppressed by using the EBG structure (see Patent Literature 1).

EBG is an application of the energy band theory of semiconductor engineering to electromagnetic-wave regions such as microwaves and millimeter waves, wherein a cyclic structure smaller than the wavelengths of target electromagnetic waves is formed of, for example, a metal material.

By virtue of an EBG structure in which the cyclic structure smaller than the wavelengths of the target electromagnetic waves is formed of a metal material, the microwaves and the millimeter waves can be present or cannot be present in the structure depending on the frequency. Therefore, propagation of radio waves can be suppressed or transmission thereof can be allowed by using the EBG structure, and suppression of unnecessary radiation and propagation suppression can be carried out by utilizing the EBG structure in, for example, an antenna.

EBG disposed on a substrate as a conductor pattern has two types, i.e., a structure using through holes as shown in Patent Literature 1 (hereinafter, 3D structure) and a planar structure. The invention of the present application relates to EBG of the planar structure.

### CITATION LIST

### Patent Literature

[Patent Literature 1] Japanese Patent Application Laid-Open No. 2008-283381

### SUMMARY OF INVENTION

### Technical Problems

EBG of the planar structure does not need through holes like those used in the 3D structure and therefore has an advantage in terms of cost, manufacturing method, etc. compared with EBG of the 3D structure. On the other hand, EBG of the planar structure has a disadvantage that the size per each EBG element is large compared with EBG of the 3D structure, and comparatively large space is required in order to cyclically arrange EBG elements having the same shape.

In propagation suppression using the EBG structure, desired suppression characteristics can be obtained when rows of the same EBG elements are repeated by a predetermined number. Therefore, it is desired that a sufficient number of rows are repeatedly arranged.

However, when they are actually put into production, various parts have to be disposed in limited space. Therefore, in many cases, it is difficult to ensure sufficient space that is necessary for forming a cyclic structure of EBG required for obtaining desired functions. If space for cyclic arrangement is insufficient in this manner, the number of repeated cyclic structures is small, and, therefore, the propagation suppression characteristics are inevitably reduced in some cases.

On the other hand, in the EBG structure which basically employs a cyclic arrangement, the space that is smaller than one EBG element of the planar structure remains in some cases as the space that is in an unused state. This insufficient residual space smaller than the size of one element in the EBG structure in this manner has been conventionally considered to be dead space which cannot be utilized for the EBG structure as unusable space.

The invention of the present application has been accomplished in view of above circumstances. It is an object of the invention to provide a planar EBG structure capable of improving the radio-wave propagation suppression effect more efficiently under a design environment in which space for disposing EBG is small and the number of repeatedly-disposed rows (cyclic structure) of EBG elements has to be comparatively reduced.

### Solution to Problems

The present invention has been accomplished in view of these problems of the conventional techniques and solves the above described problems by causing some of EBG elements of a cyclic structured arrangement to have a shape severed at an intermediate position of each element.

A planar EBG structure according to a first mode of the present invention is a planar EBG structure including a plurality of planar EBG elements arranged therein, characterized in that at least one of edge rows of rows of the planar EBG elements is severed at a predetermined position.

According to this mode, in the case in which space for cyclically arranging the planar EBG elements on a substrate is not sufficient and space smaller than one planar EBG element is remained, the row of the planar EBG elements is shaped as severed at an intermediate position, and the planar EBG elements having the shape that can be disposed in the space of the edge row are arranged. Therefore, the efficiency of suppressing propagation of radio waves can be improved more than that in the case in which the rows of the planar EBG elements is reduced by one.

The planar EBG structure according to a second mode of the present invention is characterized in that EBG conductors of the row of the planar EBG elements having the severed shape are connected to a ground. According to this mode, the propagation suppressing effect can be more improved.

The planar EBG structure according to a third mode of the present invention is characterized in that at least in one of the edge rows, each of the planar EBG elements has a shape severed to have a width of at least ¾ of the width of the planar EBG element.

Compared with the case in which the width of the planar EBG element is cut by more than ¼, high radio-wave propagation suppression efficiency can be obtained without the need of adding any additional process.

The planar EBG structure according to a fourth mode of the present invention is characterized in that in at least one of the edge rows, each of the planar EBG elements has a shape severed at an intermediate position to have a width of less than ¾ of the width of the planar EBG element; and each of the planar EBG elements having the severed shape is connected to the ground.

According to this mode, a higher radio-wave propagation suppression efficiency than that of the case in which the array of a repeated cycle is reduced by one can be obtained by connecting the planar EBG elements of the severed edge row to the ground even though the planar EBG element is severed more than ¼ of the element width.

The planar EBG structure according to a fifth mode of the present invention is characterized in that each of the planar EBG elements of the row of the planar EBG elements having the severed shape is connected to the ground via a through hole. By virtue of the through hole, each of the planar EBG elements can be connected to the ground without consuming space.

An antenna according to a first mode of the present invention is an antenna having an antenna element and planar EBG structures arranged so as to sandwich the antenna element from both sides, characterized in that

at least one of the planar EBG structures is provided with the planar EBG structure of any one of above described first to fifth modes.

When the planar EBG structures according to the present invention are used, unnecessary radiation can be suppressed, propagation of surface waves can be suppressed, and an antenna which has desired radiation characteristics and can be disposed in small space can be provided.

### Advantageous Effect of Invention

According to the present invention, the row of the EBG elements in the edge row can have a width of equal to or less than one element. Therefore, if unused space having a width smaller than that of one element is present in the case in which mounting space of a substrate is small and sufficient cyclic arrangement is difficult, the radio-wave propagation suppression efficiency can be improved by effectively utilizing the unused space.

### BRIEF DESCRIPTION OF DRAWINGS

FIG. 1 is a perspective view showing an example of an EBG element used in an edge row of a planar EBG structure according to the present invention.

FIG. 2 is a plan view showing a planar EBG structure (n=2.83) according to an embodiment of the present invention.

FIG. 3 is a graph showing results of simulations of radio-wave propagation suppression effects of planar EBG structures (n=1.83 to n=3) in the case in which part of planar EBG elements of an edge row is severed.

FIG. 4 is a graph plotting smallest values of electric field intensity and electric field intensity at a prescribed frequency of respective numbers n=1.5 to 3 of repeated arrays based on results shown in the graph of FIG. 3.

FIG. 5A is a plan view showing another embodiment of the present invention.

FIG. 5B is a data showing characteristics of the embodiment shown in FIG. 5A.

FIG. 5C is a data showing characteristics of the embodiment shown in FIG. 5A.

FIG. 6 is a plan view showing a planar EBG structure according to further another embodiment of the present invention.

FIG. 7A is a perspective view showing an example in which the planar EBG structure according to the present invention is applied to an antenna and specifically FIG. 7A is a perspective view showing an entire structure.

FIG. 7B is a perspective view showing the example in which the planar EBG structure according to the present invention is applied to the antenna and specifically FIG. 7B is a partial enlarged view thereof.

FIG. 8 is a perspective view showing an example of a general planar EBG element.

FIG. 9 is a plan view showing examples of conventional planar EBG structures in which the numbers of repeated arrays are n=11 and n=3.

FIG. 10 is a graph showing results of simulations of propagation suppression efficiency, wherein the number (n) of repeated arrays is changed to n=2, 3, 5, and 11 in planar EBG structures arranged in a repeated cycle as shown in FIG. 9.

FIG. 11 is a graph showing the numbers of repeated arrays of the planar EBG elements in the planar EBG structures, smallest values of the electric field intensity thereof, and the electric field intensity at the prescribed frequency.

FIG. 12 shows a plan view showing, as an image, a situation that the space for repeatedly arranging planar EBG rows is not enough for three rows, wherein arrangement of two rows has to be therefore employed; and FIG. 12 shows a graph showing, in comparison, differences in the radio-wave propagation suppression effects between the case of arrangement of two rows and the case of arrangement of three rows.

### DESCRIPTION OF EMBODIMENTS

Hereinafter, preferred embodiments of the present invention will be explained in detail with reference to drawings.

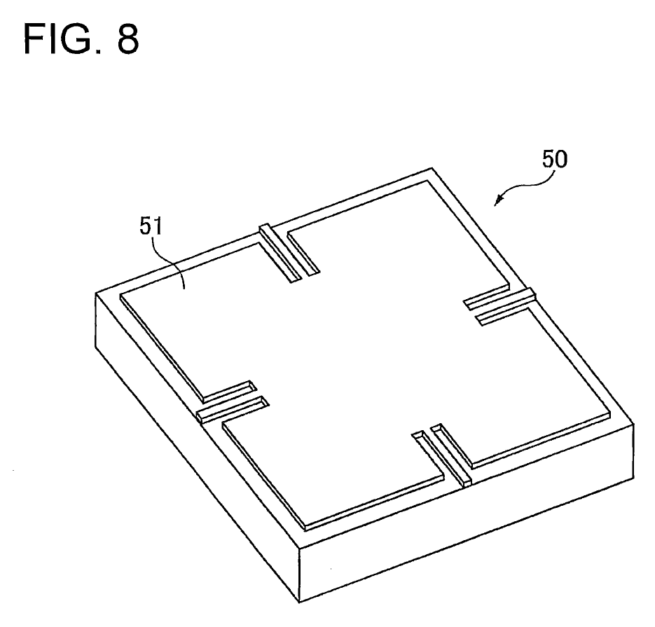

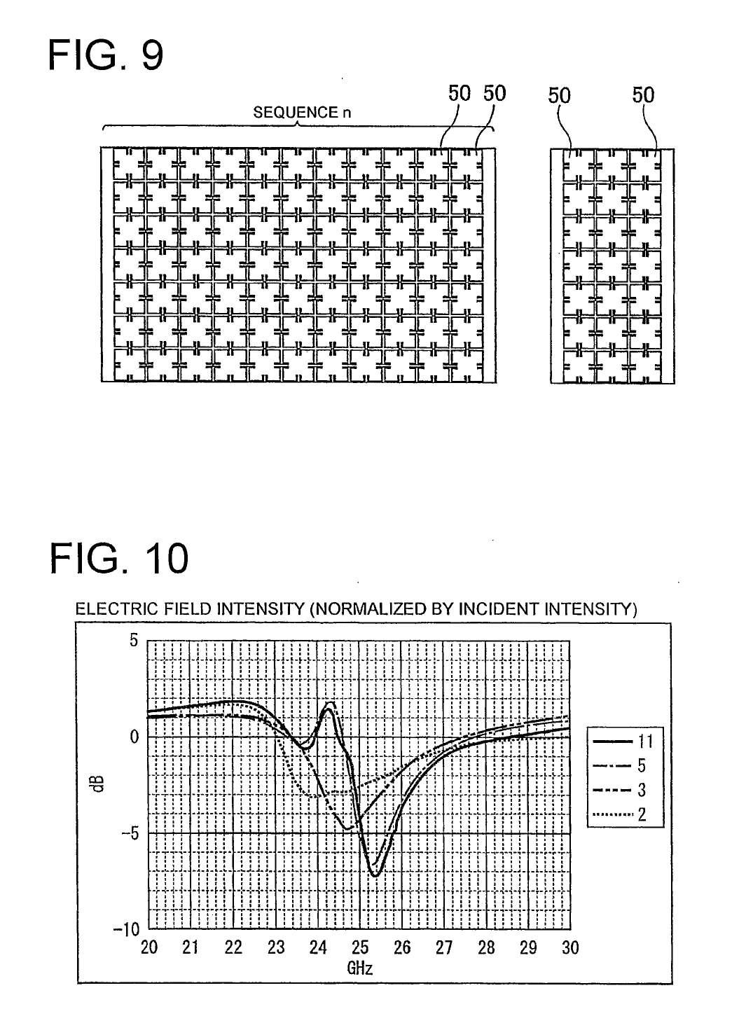

First, FIG. 8 shows a planar EBG element used in a conventional planar EBG structure arranged in a repeated cycle. As examples of the conventional planar EBG structure, FIG. 9 shows a case in which vertically-arranged element rows of the planar EBG elements of FIG. 8 are arranged in 11 rows of repeated cycles and a case in which they are arranged in three rows. In this manner, in the conventional planar EBG structures, all of the planar EBG elements having the same shapes are arranged repeatedly.

Radio-wave propagation suppression effects of the EBG structures will be explained by using simulation results. FIG. 10 is a graph showing the relations between frequencies and the radio-wave propagation suppression effects of respective numbers (n) of repeated arrays. The graph shows that the lower the electric field intensity, the higher the radio-wave propagation suppression effects. The graph shows electric field intensity (radio-wave propagation suppression effects) of respective frequencies of the cases in which the planar EBG structures as shown in FIG. 9 have the structures of repeated cycles of n=2, 3, 5, and 11 when the number of repeated arrays is n. The horizontal axis thereof shows the frequencies, and the vertical axis thereof shows the electric field intensity.

A configuration example will be shown. The EBG structure has a prescribed frequency of f₀=25.4 GHz and a wavelength λ₀=about 11.8 mm, the thickness of a substrate is about 0.08 λ₀, the size of the EBG element is about 1/4 λ₀, and the size of an EBG conductor pattern is about 0.23 λ₀. The numbers of the repeated arrays are n=2, 3, 5, and 11, and the width of the substrate is different depending on the number of the repeated arrays. The permittivity of the substrate is 4.4.

Planar waves that excite TM mode propagation entered into the planar EBG structure from the lateral surface thereof, and, after progress thereof in a transverse direction from the end of the substrate by about 0.38 λ₀, the electric field intensity at a fixed point of about 0.09 λ₀ on the EBG conductor pattern was observed.

As is understood from FIG. 10, the peak values of the electric field intensity are different depending on the number (n) of the repeated arrays. In the case of the repeated cycle n=11, the electric field intensity shows a lower-limit peak (the radio-wave suppression effect is maximum) at about 25.4 GHz, and this frequency serves as the prescribed frequency. The prescribed frequency can be controlled by the shape, size, etc. of the planar EBG element, but this is not a particular problem in the present invention.

Also the case of the repeated cycle n=5 shows changes which are approximately similar to those of n=11. However, the cases of the repeated cycles n=2 and 3 show the lower-limit peaks of the electric field intensity (the radio-wave propagation suppression effects are maximum) in the vicinities of about 23.8 GHz and about 24.8 GHz, respectively.

According to this graph, it can be understood that the larger the number n of the repeated arrays, the more stable the radio-wave propagation suppression effect, and the radio-wave propagation suppression effects having similar characteristics are obtained at n=5 or higher. A problem in this case is that the radio-wave propagation suppression effect becomes smaller (the lower-limit peak value of the electric field intensity becomes higher) when the number of the repeated arrays becomes smaller.

More specifically, according to the graph of FIG. 10, in the case in which the numbers n of the repeated arrays are equal to 2 and 3, the largest lower-limit peak values of the electric field intensity are −4.8 dB and −3 dB, respectively, and it can be understood that the radio-wave propagation suppression effects thereof are greatly lowered compared with the case in which the number n of the repeated arrays is equal to 5.

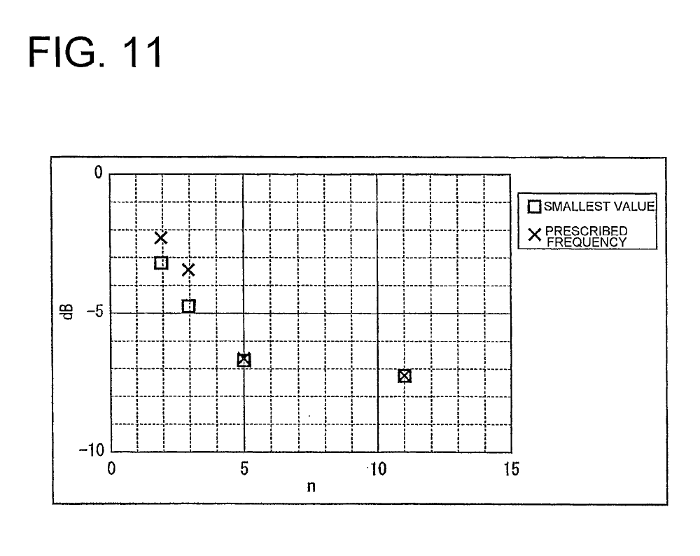

FIG. 11 was created based on the data of FIG. 10 and is showing the smallest values (lower-limit peak values) of the electric field intensity of the planar EBG structures having the numbers n of the repeated arrays and showing the values of the electric field intensity at the prescribed frequency f₀=25.4 GHz. For example, as is understood from FIG. 10, FIG. 11 plots the smallest value (lower-limit peak value) −7 dB of the electric field intensity (frequency: about 25.3 GHz) and the electric field intensity of about −6.8 dB at the prescribed frequency of 25.4 GHz in the case in which the number n of the repeated arrays is equal to 5. The lower-limit peak value and the electric field intensity of the prescribed frequency are almost the same.

On the other hand, due to a phenomenon that the lower-limit peak frequency is lowered as the number of the repeated arrays becomes smaller, for example as is understood from FIG. 10, in the case in which the number n of the repeated arrays is equal to 3, the smallest value of the electric field intensity is about −4.9 dB (frequency: about 24.8 GHz), while the electric field intensity is about −3 dB at the prescribed frequency of f₀=25.4 GHz. As plotted in FIG. 11, both of them are largely deviated from each other. From the viewpoint of radio-wave propagation suppression, the electric field intensity is preferred to be as low as possible. It is also preferred that both of them be not largely deviated from each other in actual designing such as matching of frequencies.

According to FIG. 11, it can be understood that in the cases of the numbers n=11 and n=5 of the repeated arrays, the smallest values of the electric field intensity are low, and the smallest values and the electric field intensity of the prescribed frequency are almost the same; however, in the cases of n=3 and n=2, the smallest values of the electric field intensity are high, and the smallest values and the electric field intensity of the prescribed frequencies are deviated from each other. In other words, it can be understood that deterioration in the radio-wave propagation suppression effect is notable when the number n of the repeated arrays is equal to or less than n=5.

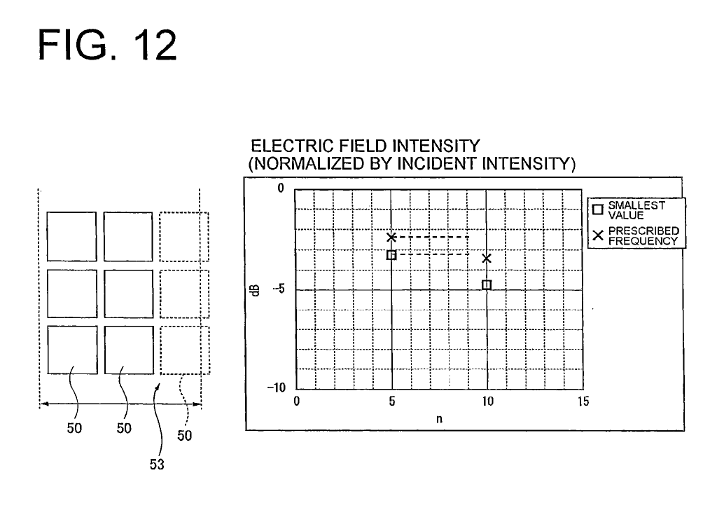

The left drawing in FIG. 12 is a drawing showing, as an image, an example of arrangement space in a case in which the planar EBG structure is actually mounted. In actual mounting, the size of a substrate is limited, and mounting space of the EBG structure is also limited. Therefore, the space in which a desired number of EBG element rows can be disposed often lacks. Also, in a case in which rows of a maximum number of EBG elements are to be disposed in small space, insufficient residual space that does not have a width of one element is often generated. FIG. 12 shows that residual space 53 is not enough for the number 3 of repeated arrays (n=3), and not more than two rows of planar EBG element rows can be disposed (n=2). In this case, the residual space 53 has been dead space in terms of the EBG structure.

A graph shown in the right side of FIG. 12 shows the electric field intensity of the cases in which the number n of the repeated arrays is n=2 and n=3. As is understood from the graph, in the case of n=2 and the case of n=3, it can be understood that the radio-wave propagation suppression effects are largely different both in the cases of the smallest value and the prescribed frequency. Therefore, effectively utilizing the residual space 53 is required.

As a result of study for obtaining a planar EBG structure capable of effectively utilizing this residual space, the invention of the present application has been found out that radio-wave propagation suppression effects better than that of a case in which rows of the same structures are simply provided can be obtained depending on conditions of severing positions and severing ends when EBG elements of an edge-part row are severed at intermediate positions thereof.

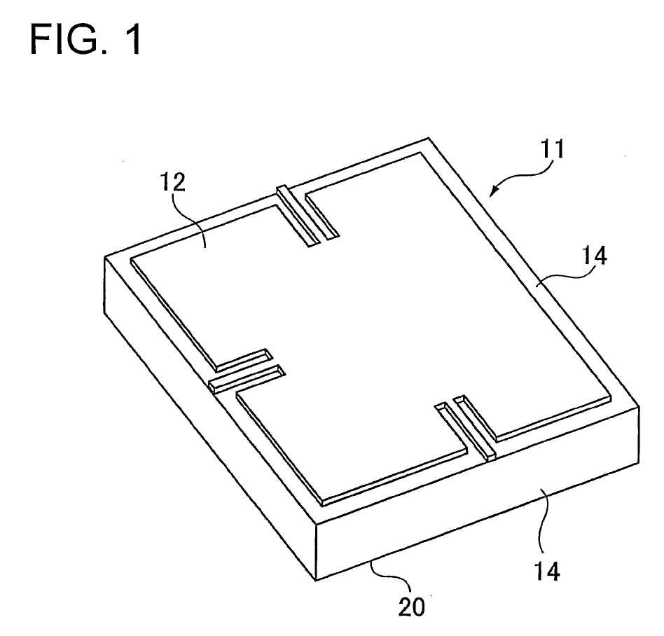

More detailed explanation will be given by using FIG. 1 to FIG. 4.

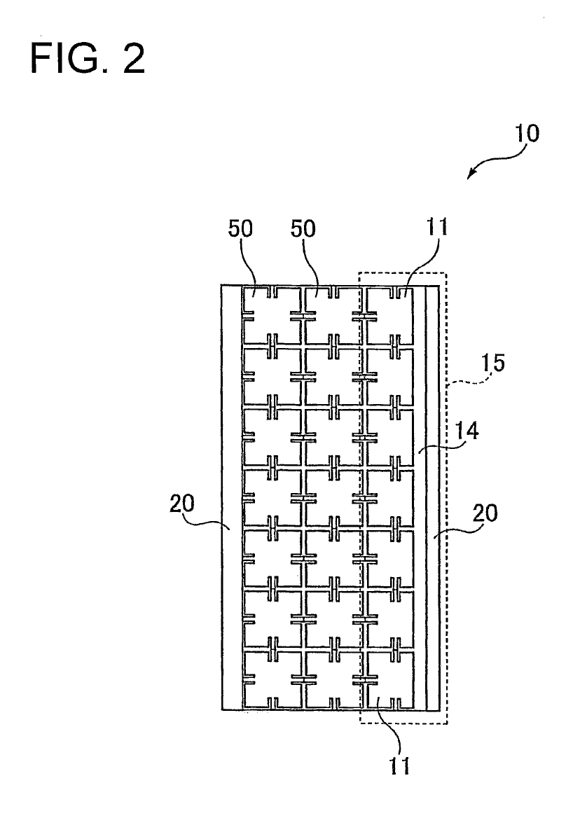

In the invention of the present application, in order to arrange effective EBG elements in the residual space 53, which is dead space, a row of EBG elements each of which having a shape obtained by severing a normal EBG element at an intermediate position is disposed in the residual space 53 as EBG elements of an edge row. FIG. 1 shows the EBG element 11 having the shape obtained by severing at the intermediate position. FIG. 2 shows a planar EBG structure 10 according to an embodiment of the present invention, wherein the planar EBG elements 11 each of which having the shape obtained by severing at the intermediate position are arranged in the edge row.

As shown in FIG. 1, the planar EBG element 11 has a structure that an EBG conductor 12 is severed at an intermediate position. In FIG. 2, normal planar EBG elements 50 are provided in two rows, and the planar EBG elements 11 as shown in FIG. 1 are disposed as an edge row like 15 shown by a broken line, wherein the planar EBG element rows of in total three rows are provided. A ground 20 is provided in a lower side of a substrate 14 (see FIG. 1) serving as a dielectric body.

The illustration shown herein is an example, and the shape of the EBG elements of the planar structure and the way of arrangement thereof are not limited to those of FIG. 1 and FIG. 2.

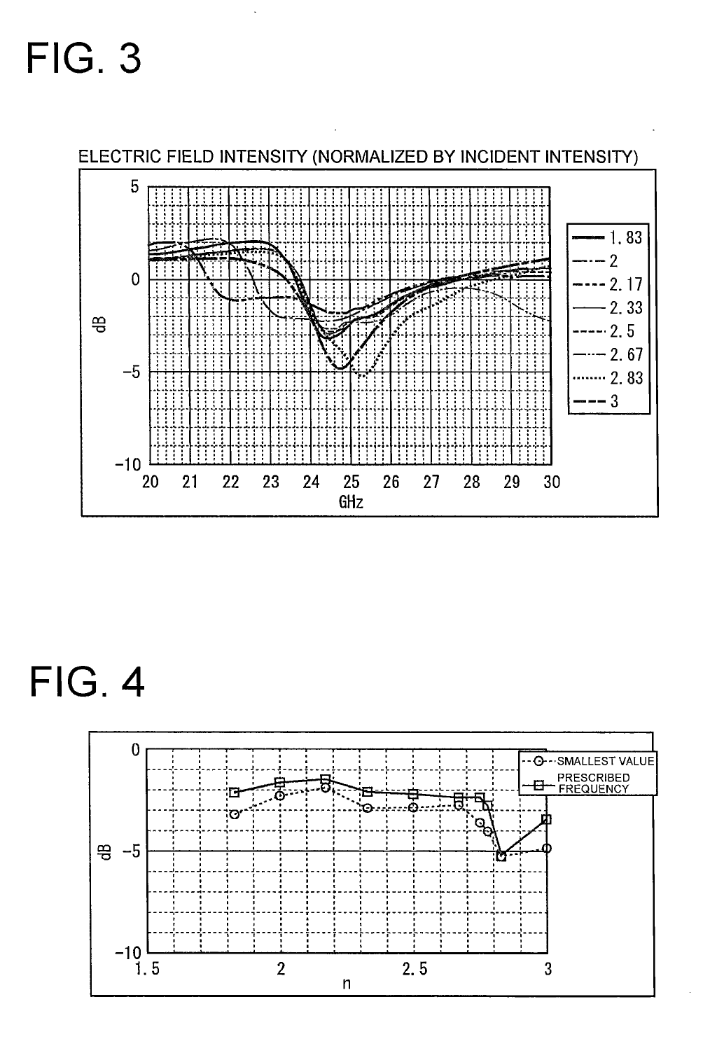

FIG. 3 is a graph showing characteristics in the cases in which the width of the planar EBG elements 11 serving as the edge row is changed, wherein the relation between radio-wave propagation suppression effects and frequencies corresponding to severing positions is shown.

Calculation conditions are the same as the measurement conditions of FIG. 10 except that the width of the planar EBG elements 11 of the edge row is changed in a case in which the number of repeated arrays is n=2 or 3 with a substrate width of about n=3 rows. The numbers of legends represent the numbers of the repeated arrays, and the number of decimals represents the width of a fractional row. More specifically, 1.83 represents that the number of the repeated arrays is n=2 and that the width of the planar EBG element 11 in the edge row is 0.83 times that of the normal planar EBG element 50. Also, 2.67 represents that the number of the repeated arrays is n=3 and that the width of the planar EBG element 11 in the edge row is 0.67 times that of the normal planar EBG element 50. Thus, characteristic changes in the cases in which the width of the planar EBG element 11 in the edge row is changed when the number of the repeated arrays is n=2 or 3 can be found out.

FIG. 4 is a graph created based on FIG. 3 and, as well as FIG. 11, is a drawing that shows lower-limit peak values (smallest values) of radio-wave propagation suppression effects and electric field intensity at the prescribed frequency f0 corresponding to severing positions.

According to this, it can be understood that, in the cases of the EBG structures having a row number of 2 and a row number of 3, the radio-wave propagation suppression effect is better at n=2.83 than that of n=3, and the radio-wave propagation suppression effect is higher also at n=1.83 than that of n=2. On the other hand, it can be also understood that the radio-wave propagation suppression effects are not good at n=2.67 to n=2.

When the above facts were comprehensively judged, it was found out that, roughly, when the EBG element at the edge part had a width of approximately ¾ or larger and less than 1 of that of the EBG element, the electric-field suppression effect was higher than those of the cases of the row number 2 or the row number 3 regarding the electric field intensity at both of peak of the radio-wave propagation suppression effect and at the prescribed frequency.

The case in which the planar EBG element is severed by less than ¼ of the width of the planar EBG element (¾ or more thereof remain) is effective. The radio-wave propagation suppression effect is notable in the case of n=2.83 rather than the case in which the repeated cycle n is exactly 3.

Therefore, in a planar EBG structure in which a large number of repeated arrays cannot be ensured, the planar EBG elements are desired to have a structure that the width of each EBG element in the edge-part row is ¾ to less than 1 times the width of one EBG element.

The background of above description will be technically explained below. Generally, it has been considered that EBG having a planar structure obtains a propagation suppression effect as a result of parallel resonance and increased impedance caused by L components and C components formed between EBG elements. On the other hand, the present invention has elucidated that the edge parts of the EBG elements of the edge row contributes to propagation suppression instead of the L components and C components between the EBG elements. The EBG elements resonate not only between the elements but also including the C components present between there and a ground. When the edge parts of the EBG elements of the edge row have an open boundary with no EBG elements therearound, C components are present only between there and the ground, and resonance including the edge part has different conditions from those of the resonance between the EBG elements. Strong resonance and effective propagation suppression effects can be obtained by adjusting conditions such as adjustment of frequencies. The present embodiment shows that reducing the size of the elements in the edge row to be smaller than the EBG elements by some degree is effective.

On the other hand, if the edge parts of the EBG elements of the edge row are short-circuited to be grounded, an effect different from parallel resonance between the EBG elements can be imparted. It is conceived that an electric wall is formed because of the short-circuit with the ground, and a partial mirror effect is obtained. In this process, the short-circuit in the vicinity of the center of the EBG element does not affect formation of the parallel resonance formed between the EBG elements. Furthermore, the short-circuit in the edge part can impart conditions opposite to those of the above described open boundary in terms of circuit understanding. In a region in which characteristics are deteriorated by open conditions, optimal radio-wave suppression characteristics can be obtained in the entire region by providing short-circuit conditions. Examples of conditions will be shown below whether which one of open and short-circuit is suitable depending on the size of the EBG element of the edge row.

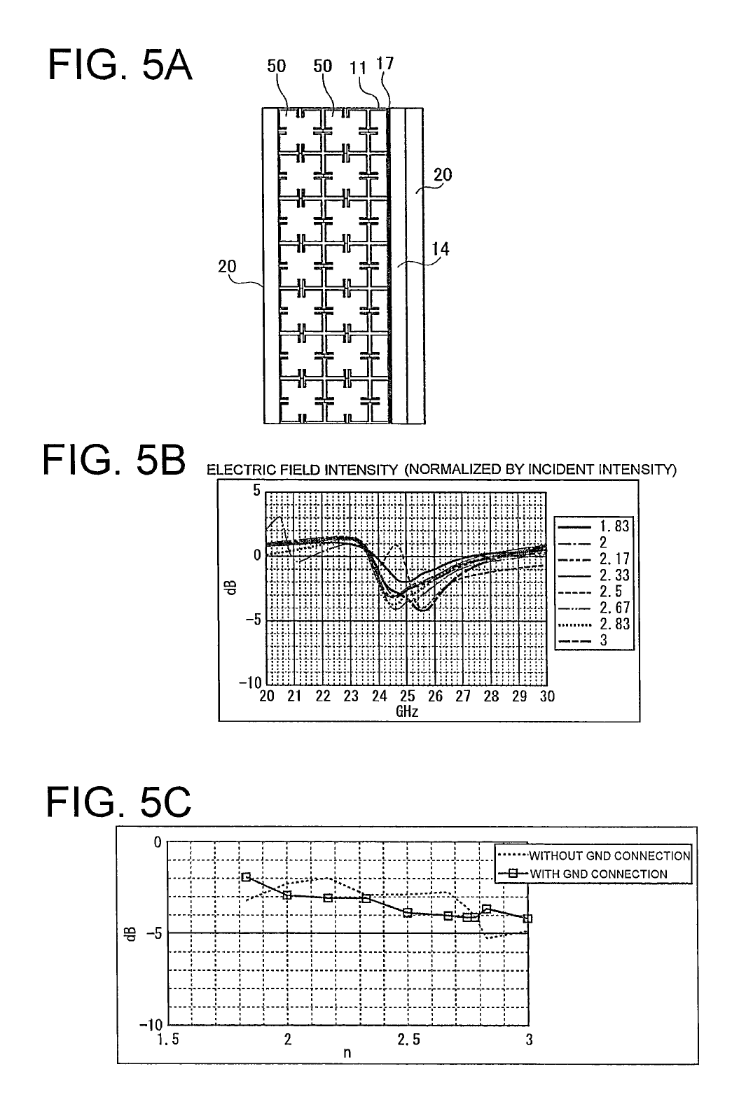

FIG. 5A is a plan view showing another embodiment of the present invention. In this embodiment, a ground connection surface 17, which connects the EBG conductors 11 to a ground 20, is provided in the severed surface side of the planar EBG elements of the edge row. FIGS. 5B and 5C show data obtained under the same conditions as those of FIG. 3 and FIG. 4 except ground connection. FIG. 5C shows values plotting only the smallest values of the case with GND connection and the case without GND connection. The smallest values shown in FIG. 4 are used as the data of the case without GND connection.

As is understood from FIG. 5C, it can be understood that the EBG element radio-wave propagation suppression effect larger than that of the state of n=2 (no severed edge row is provided) is present when the EBG conductors 11 are connected to GND even when each of the planar EBG elements in the edge row is severed by more than ¼. Therefore, in the case in which the EBG elements of the edge row are to be severed by more than ¼, the EBG conductors 12 of the edge row is desired to be grounded to the GND 20.

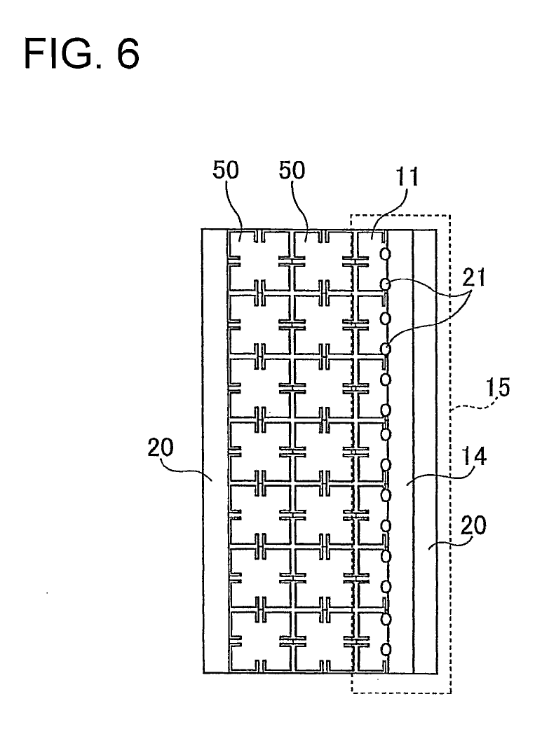

As a configuration of grounding the EBG conductors 11 of the edge row to the GND 20, as shown in FIG. 6, through holes 21 penetrating from the EBG conductors 11 to the dielectric body (substrate) 14 and connected to the GND 20 can be configured to be provided.

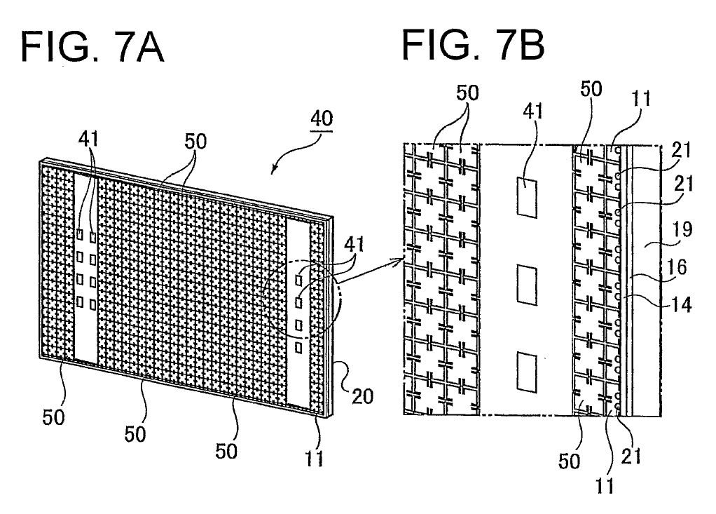

FIGS. 7A and 7B show an example of an antenna using the EBG structure according to the present invention. FIG. 7A is a perspective view showing the entire structure (external appearance) of the antenna 40, and FIG. 7B is a partial enlarged view thereof. The antenna 40 is provided with a plurality of antenna elements 41, and both sides of the antenna are sandwiched by a plurality of planar EBG structures. In a right edge row, a row of planar EBG elements are severed, and the EBG conductors of the EBG elements 11 are connected to GND via through holes 21. In the example in FIGS. 7A and 7B, a dielectric body 16 and a shield case 19 are provided below the dielectric body 14 via GND. A left edge row is similar to this.

When the planar EBG elements 50 and 11 are arranged without wasting the space of the edge rows in this manner, an antenna which has desired radiation characteristics and can be disposed in small space can be provided.

### REFERENCE SIGNS LIST

10 PLANAR EBG STRUCTURE ACCORDING TO THE INVENTION OF THE PRESENT APPLICATION
11 PLANAR EBG ELEMENT USED IN EDGE ROW OF THE INVENTION OF THE PRESENT APPLICATION
12 EBG CONDUCTOR
14 DIELECTRIC BODY (SUBSTRATE)
17 GROUND CONNECTION LINE
19 SHIELD CASE
20 GND (GROUND)
21 THROUGH HOLE
40 ANTENNA
41 ANTENNA ELEMENT
50 PLANAR EBG ELEMENT
51 EBG CONDUCTOR
53 RESIDUAL SPACE

1. A planar EBG structure including a plurality of planar EBG elements arranged therein, wherein
at least one of edge rows of rows of the planar EBG elements is severed at a predetermined position.

2. The planar EBG structure according to claim 1, wherein
EBG conductors of the row of the planar EBG elements having the severed shape are connected to a ground.

3. The planar EBG structure according to claim 1, wherein,
at least in one of the edge rows, each of the planar EBG elements has a shape severed to have a width of at least ¾ times the width of the planar EBG element.

4. The planar EBG structure according to claim 2, wherein,
in at least one of the edge rows, each of the planar EBG elements has a shape severed at an intermediate position to have a width of less than ¾ of the width of the planar EBG element; and each of the planar EBG elements having the severed shape is connected to the ground.

5. The planar EBG structure according to claim 4, wherein
the planar EBG element in the edge row is connected to the ground via a through hole.

6. An antenna comprising an antenna element and a planar EBG structure arranged so as to sandwich the antenna element from both sides, wherein
at least one of edge rows of the planar EBG structure is provided with the planar EBG structure according to any one of claims 1 to 5.
